(19) United States
(12) Patent Application Publication
(10) Pub. No.: US 2024/0014335 A1
(43) Pub. Date: Jan. 11, 2024

(54) PHOTOELECTRIC CONVERSION ELEMENT MATERIAL, METHOD FOR PRODUCING PHOTOELECTRIC CONVERSION ELEMENT MATERIAL, AND INK IN WHICH SEMICONDUCTOR NANOPARTICLES ARE DISPERSED

(71) Applicants: TANAKA KIKINZOKU KOGYO K.K., Tokyo (JP); UNIVERSITY INDUSTRY FOUNDATION, YONSEI UNIVERSITY, Seoul (KR)

(72) Inventors: Hiroki SATO, Tsukuba-shi (JP); Yuusuke OHSHIMA, Tsukuba-shi (JP); Tatsuya NAKAZAWA, Isehara-shi (JP); Hyung Jun KIM, Seoul (KR); Dong Hyun KIM, Seoul (KR)

(73) Assignees: TANAKA KIKINZOKU KOGYO K.K., Tokyo (JP); UNIVERSITY INDUSTRY FOUNDATION, YONSEI UNIVERSITY, Seoul (KR)

(21) Appl. No.: 18/270,464

(22) PCT Filed: Dec. 27, 2021
(86) PCT No.: PCT/JP2021/048457

§ 371 Date: Jun. 29, 2023

(30) Foreign Application Priority Data
Jan. 6, 2021 (JP) 2021-001129

(51) Int. Cl. H01L 31/032; H01L 31/036; H01L 31/18; C09K 11/58; C09K 11/74

(52) U.S. Cl. CPC H01L 31/032; H01L 31/036; H01L 31/18; C09K 11/582; C09K 11/7407

(57) ABSTRACT

The present invention relates to a photoelectric conversion element material provided with a base material and a light-receiving layer including a semiconductor film formed on the base material. The semiconductor film that forms this light-receiving layer includes Ag₂₋ₓBiₓSₓ₊₁ (x is an integer of 0 or 1) and has a crystallite diameter of 10 nm or more and 40 nm or less. The light-receiving layer can be produced by applying an ink containing the semiconductor nanoparticles dispersed in a dispersion medium to a base material and then firing the ink at 200° C. or higher and 350° C. or lower. The photoelectric conversion element material of the present invention has an absorption property with respect to light with wavelengths in the near infrared region and excellent photoresponsivity.

### BACKGROUND OF THE INVENTION

### Field of the Invention

The present invention relates to a photoelectric conversion element material that is used for light sensors and the like and particularly to a photoelectric conversion element material provided with a light-receiving layer including a predetermined metal chalcogenide on a base material. In addition, the present invention relates to an ink where semiconductor nanoparticles are dispersed, the semiconductor nanoparticles being suitable for forming light-receiving layers in photoelectric conversion element materials.

### Description of the Related Art

As a configuration material of photoelectric conversion elements or light-emitting elements that are mounted in a variety of optical semiconductor devices such as solar cells, light sensors and light-emitting devices (LEDs), the use of semiconductor nanoparticles that are referred to as quantum dots (QDs) is expected. Semiconductors develop a quantum confinement effect when being composed of nano-scale fine particles and have a band gap based on the particle diameters. Therefore, the adjustment of the band gap by controlling the composition and particle diameters of semiconductor nanoparticles makes it possible to arbitrarily set light-emitting wavelengths or absorption wavelengths.

Semiconductor nanoparticles are capable of contributing to the size reduction and thickness reduction of semiconductor devices including a photoelectric conversion element as a light-receiving element. For example, in photoelectric conversion portions of CMOS image sensors that have been conventionally mounted in video cameras, mobile phone cameras and the like, silicon photodiodes have been in use. In this CMOS image sensor, it is required to form a silicon thin film having a certain degree of thickness (2 to 3 μm) for light absorption that is necessary for sensor driving. However, semiconductor nanoparticles have a high quantum efficiency and also have a characteristic of a high absorption coefficient. This makes it possible to make the thicknesses of light-receiving elements in CMOS image sensors thinner (less than 1 μm) than those with existing techniques.

In addition, the characteristics of semiconductor nanoparticles the light-emitting and absorption wavelengths of which can be adjusted can be a starting point of the development of photoelectric conversion elements intended for light in a wavelength range which has been difficult to handle with conventional semiconductor materials. Particularly, in recent years, there has been a demand for the development of a photoelectric conversion element having responsiveness to light in the near infrared region. Examples of the photoelectric conversion element in which near infrared light is used include light-receiving elements that are applied to LIDAR (light detection and ranging) or short-wave infrared (SWIR) image sensors. LIDAR refers to a remote sensing system in automobile self-driving, drones, ships and the like. LIDAR is a measurement system in which a subject is irradiated with laser light, a reflected light is sensed with a light-receiving element and the distance or angle of the subject is detected. LIDAR is deemed to be an important device in the recent development of self-driving techniques. In addition, SWIR image sensors are also devices the demand for which in the future is expected to increase in the fields of food inspection, the agricultural field, drones and the like.

Photoelectric conversion elements such as LIDAR or SWIR image sensors exemplified above are required to have favorable response characteristics to light in the near infrared region. Regarding this, it was difficult for conventional semiconductor materials to meet this requirement. Silicon that is used in the above-described CMOS image sensors has a difficulty in responding to near infrared light owing to its band gap value. Therefore, the effectiveness of semiconductor nanoparticles is also expected from the viewpoint of such a response to near infrared light.

### PRIOR ART DOCUMENT

### Patent Document

### Patent Document 1

Japanese Patent Application Laid-Open No. 2020-40847

### Patent Document 2

Japanese Patent Application Laid-Open No. 2020-15802

### SUMMARY OF THE INVENTION

### Technical Problem to be Solved by the Present Invention

At the moment, there are not so many reported cases regarding semiconductor nanoparticles having responsiveness to light in the near infrared region. While it is possible to adjust the band gap of semiconductor nanoparticles by controlling the particle diameters, the adjustable range is based on the band gap of a semiconductor that configures the nanoparticles. Based on the photon energy formula (E=hc/λ (h: Planck constant, c: speed of light, λ: wavelength)), the band gap of semiconductor nanoparticles needs to be approximately 1.77 eV or less in order to acquire responsiveness in the near-infrared region (the wavelength region is set to 700 nm to 2500 nm). However, there are not so many semiconductor materials with such a narrow band gap.

As semiconductors that configure semiconductor nanoparticles, metal chalcogenides, which are binary or tertiary compounds of one or two metals belonging to transition metals (Pb, Cd or the like) and a chalcogen element except oxygen (S, Se, Te or the like) are known. As a metal chalcogenide that has responsiveness to near infrared light and has been successfully put into practical use when made into semiconductor nanoparticles, PbS is known. However, PbS includes Pb, which makes it hard to say that PbS is a suitable semiconductor material owing to the recent environmental issues and the like. Therefore, studies of the configurations and compositions of semiconductor materials that satisfy this requirement become necessary.

In addition, even when metal chalcogenides having a response characteristic to near infrared light have been found and it has become possible to manufacture semiconductor nanoparticles of the metal chalcogenide, additional studies regarding element materials having a high photoresponse characteristic in consideration of practicality are also required. As an aspect for applying semiconductor nanoparticles to photoelectric conversion elements and the like, semiconductor thin films, which serve as light-receiving layers, have been formed by dispersing semiconductor nanoparticles in an appropriate dispersion medium to produce an ink (dispersion) and applying this ink to a base material. In order to improve the response characteristic of photoelectric conversion elements to near infrared light, the characteristics of semiconductor nanoparticles are important, but the characteristics of the semiconductor nanoparticles when made into thin films as described above become more important.

The present invention has been made based on the above-described background, and an objective of the present invention is to propose semiconductor nanoparticles including a metal chalcogenide having a light absorption property in the near infrared region and to provide a photoelectric conversion element material that includes a semiconductor thin film formed of these semiconductor nanoparticles and is provided with a light-receiving layer having excellent photoresponsivity. In addition, an ink including the above-described semiconductor nanoparticles and a method for producing a semiconductor thin film having a suitable configuration using this ink will also be clarified.

### Solution to Problem

In order to solve the above-described problems, first, the present inventors studied the composition of a metal chalcogenide having a suitable band gap and being capable of exhibiting responsiveness in the near infrared region when made into semiconductor nanoparticles. In addition, the present inventors paid attention to AgBiS₂ and Ag₂S, which are Ag-based chalcogenides. These Ag-based chalcogenides have a band gap of 1 eV or less in a bulk state and are thus considered to be capable of exhibiting responsiveness to near infrared light when made into semiconductor nanoparticles.

Therefore, the present inventors confirmed the near infrared light absorption properties of semiconductor nanoparticles including AgBiS₂ and Ag₂S and also confirmed that semiconductor nanoparticles can be made into inks in a suitable state and, furthermore, can be formed into semiconductor thin films, which serve as light-receiving layers. In addition, based on these studies, the present inventors performed the configurations and studies of thin films having improved responsiveness to near infrared light regarding AgBiS₂ thin films and Ag₂S thin films formed of semiconductor nanoparticles and got an idea of the present invention.

The present invention that solves the above-described problems is a photoelectric conversion element material provided with a base material and a light-receiving layer including a semiconductor film formed on the base material, in which the semiconductor film includes Ag₂₋ₓBiₓSₓ₊₁ (x is an integer of 0 or 1) and the crystallite diameter of the semiconductor film is 10 nm or more and 25 nm or less.

Hereinafter, the configuration of the photoelectric conversion element material provided with a light-receiving layer including a metal chalcogenide thin film of the present invention and a method for producing the material will be described. As described above, the photoelectric conversion element material of the present invention includes a base material and a light-receiving layer on the base material as a basic configuration.

### A Configuration of Photoelectric Conversion Element Material of the Present Invention

### A-1 Base Material

The base material is a member for supporting the light-receiving layer including a semiconductor film of a metal chalcogenide. The base material may be any material as long as the material is capable of achieving this objective. Examples of material for the base material include glass, quartz, silicon, ceramic, and metal. In addition, the shape and dimension of the base material are not particularly limited.

### A-2 Light-Receiving Layer

(a) Composition of Light-Receiving Layer

The semiconductor film that configures the light-receiving layer in the photoelectric conversion element material of the present invention is a thin film including Ag₂₋ₓBiₓSₓ₊₁ (x is 0 or 1), which is a Ag-based metal chalcogenide, that is, AgBiS₂ or Ag₂S. The band gaps of these metal chalcogenides are less than 1 eV, that is, 0.8 eV (AgBiS₂) and 0.9 eV (Ag₂S) in a bulk state, and thus the nanoparticles of these metal chalcogenides are considered to have responsiveness in the near infrared region.
(b) Structure of Light-Receiving Layer

The light-receiving layer including the semiconductor film is a thin film that is formed by depositing the nanoparticles of AgBiS₂ or Ag₂S. In the present invention, for improving the photoresponsivity, the crystallite diameter of the semiconductor nanoparticles of AgBiS₂ or Ag₂S in the thin film is regulated. The crystallite diameter is the largest region that can be regarded as a single crystal in the semiconductor nanoparticles. The semiconductor nanoparticles in the thin film of the present invention are polycrystalline substances or single-crystal substances, and the crystallite diameter is smaller than or equal to the particle diameters of the semiconductor nanoparticles. In the present invention, the crystallite diameter of AgBiS₂ or Ag₂ S is set to 10 nm or more and 40 nm or less. The reason for the photoresponsivity being related to the crystallite diameter in the light-receiving layer including a semiconductor of the present invention is not clear, but the present inventors assume that enhancement of crystallinity optimizes the crystal structure of AgBiS₂ or Ag₂S. In a state where the crystallite diameter of AgBiS₂ or Ag₂ S is less than 10 nm, the crystallinity is low, there is no difference from a state before the formation of the thin film (a state of the semiconductor nanoparticles in an ink), and there is no effect of improving the photoresponsivity. On the other hand, in a state where the crystallite diameter of AgBiS₂ or Ag₂S exceeds 40 nm, it is considered that the coarsening of AgBiS₂ particles or Ag₂ S particles or the decomposition of a compound occurs partially, and, in this case as well, the photoresponsivity deteriorates. The crystallite diameter of AgBiS₂ and Ag₂S is more preferably nm or more and 25 nm or less.

The crystallite diameter is the minimum unit capable of contributing to diffraction when a substance is irradiated with X-rays and thus can be measured by X-ray diffraction (XRD). Regarding the present invention, when the crystallite diameter of the light-receiving layer is measured by XRD, in AgBiS₂, diffraction peaks are shown at 2θ=near 27° and near 31° owing to CuKα rays. In addition, in Ag₂S, diffraction peaks are shown at 2θ=near 26° and near 38° owing to CuKα rays. In the present invention, it is preferable to measure the crystallite diameters of AgBiS₂ and Ag₂S based on the diffraction peaks at 2θ=near 31° and 2θ=near 38°, respectively. As described below, in the present invention, the crystallite diameter can be adjusted by performing a thermal treatment on the thin film of AgBiS₂ or Ag₂S at a predetermined temperature. In AgBiS₂ or Ag₂S, what can be clearly confirmed at any thermal treatment temperature is the peak at 2θ=near 38°. The crystallite diameter can be calculated based on the Scherrer equation by calculating the full-width at half maximum of the diffraction peak.

In addition, the surface roughness of the light-receiving layer in the photoelectric conversion element material of the present invention is preferably 2 nm or more and 15 nm or less. An increase in surface roughness is considered to affect the distance between particles. In photoelectric conversion elements, the distance between particles acts on the efficiency of the transfer of electrons between the particles, and thus the surface roughness is preferably set within the above-described range. In addition, the thickness of the light-receiving layer including the semiconductor thin film is preferably set to 10 nm or more.

The photoelectric conversion element material of the present invention has an absorption property and responsiveness with respect to light in the near infrared region. It is preferable that the photoelectric conversion element material has responsiveness with respect to light in the near-infrared region where the wavelengths are 700 nm or more and 1200 nm or less. This characteristic is attributed to the band gap of AgBiS₂ or Ag₂S, which is the semiconductor that forms the light-receiving layer.

Therefore, the photoelectric conversion element material of the present invention is applied to semiconductor devices that handle light having wavelengths in the near infrared region, and the applications are not particularly limited. For example, the photoelectric conversion element material can be used as a semiconductor material in a broad range of applications such as light-receiving elements, optical sensors and light detectors. In particular, the photoelectric conversion element material has excellent light sensitivity in the near infrared region and is thus suitable for light-receiving elements such as LIDAR and SWIR image sensors.

### B Method for Producing Photoelectric Conversion Element Material of the

### Present Invention

In the producing of the photoelectric conversion element material of the present invention, it is necessary to form a semiconductor thin film (AgBiS₂ thin film or Ag₂S thin film), which serves as the light-receiving layer, on the above-described base material. In the present invention, the AgBiS₂ thin film or Ag₂ S thin film is formed by applying an ink in which the semiconductor nanoparticles of AgBiS₂ or Ag₂ S are dispersed. In addition, in order to set the crystallite diameter of the above-described semiconductor within a preferable range, a treatment of firing a semiconductor layer after the application and enhancing the crystallinity is performed. Hereinafter, these characteristic portions will be described.

### B-1 Semiconductor Nanoparticle Ink of the Present Invention

In the present invention, an ink containing semiconductor nanoparticles dispersed in a dispersion medium is applied. The semiconductor nanoparticles include Ag₂₋ₓBiₓSₓ₊₁ (x is 0 or 1). These semiconductor nanoparticles that disperse in the ink have particle diameters of 3 nm or more and 20 nm or less and have a crystallite diameter of 3 nm or more and 20 nm or less. The reason for regulating the particle diameters of the semiconductor nanoparticles as described above is to have a band gap in the near-infrared region while holding the quantum confinement effect of quantum dots. In addition, the crystallite diameter is the maximum value of regions that are regarded as single crystals in the semiconductor nanoparticles and is thus deemed to be preferably as large as possible within the above-described particle diameter range.

The semiconductor nanoparticles are dispersed in the dispersion medium in a state protected by a protective agent. The protective agent is an additive for suppressing the agglomeration and coarsening of the semiconductor nanoparticles and stabilizing the dispersion state. The agglomeration and coarsening of the semiconductor nanoparticles affects the response characteristic when the semiconductor nanoparticles are applied to the base material and made into the light-receiving layer and thus needs to be avoided at all costs. The protective agent is an organic compound that bonds to the semiconductor nanoparticles and suppresses the agglomeration of the nanoparticles caused by the repulsive force between the protective agents.

The protective agent in the ink of the present invention is composed of at least any one of a long-chain alkylamine, a long-chain carboxylic acid and a thiol. Specifically, the long-chain alkylamine refers to a linear or branched alkylamine having 6 or more carbon atoms. Specific examples of a preferable alkylamine include octylamine (having 8 carbon atoms), decylamine (having carbon atoms), dodecylamine (having 12 carbon atoms), tetradecylamine (having 14 carbon atoms), and oleylamine (having 18 carbon atoms). In addition, the carboxylic acid is a linear or branched carboxylic acid having 6 or more carbon atoms. Specific examples of a preferable carboxylic acid include octanoic acid (having 8 carbon atoms), lauric acid (having 12 carbon atoms), myristic acid (having 14 carbon atoms), and oleic acid (having 18 carbon atoms). In addition, the thiol is a linear or branched thiol having 6 or more carbon atoms. Specific examples of a preferable thiol include octanethiol (having 8 carbon atoms), dodecanethiol (having 12 carbon atoms), and octadecanethiol (having 18 carbon atoms). A protective agent produced by combining one or more long-chain alkylamines, long-chain carboxylic acids or thiols as described above can be applied.

As the dispersion medium of the semiconductor nanoparticle ink, an organic solvent with a low polarity is used. Specifically, each of toluene, hexane, chloroform, dichloromethane, cyclohexane, octanol and the like or a solvent mixture of the organic solvents is preferable.

The semiconductor nanoparticle ink of the present invention can be produced by synthesizing the nanoparticles of AgBiS₂ and Ag₂S in advance and dispersing these in the dispersion medium. Regarding the AgBiS₂ nanoparticles, sulfur or a sulfur compound is added to a solution mixture obtained by mixing a Ag salt (for example, silver acetate, silver oxalate, silver nitrate, silver carbonate, silver diethyldithiocarbamate or the like) and a Bi salt (bismuth acetate, bismuth nitrate or the like) with the protective agent and reacted, whereby AgBiS₂ nanoparticles to which the protective agent bonds are synthesized. In addition, the Ag₂S nanoparticles can be synthesized by mixing and reacting a sulfur compound (thiourea or sulfur), together with the protective agent, with the same Ag salt as described above. Both nanoparticles can be made into an ink by separating the nanoparticles from a reaction liquid after the synthesis, appropriately washing the nanoparticles and then adding the nanoparticles to the dispersion medium.

### B-2 Method for Forming Light-Receiving Layer on Base Material (Step of Applying and Firing Ink)

The light-receiving layer including the semiconductor film in the present invention can be formed by applying the above-described ink containing the semiconductor nanoparticles dispersed therein to the base material and firing the ink. A method for applying the ink is preferably a spin coating method in order to uniformly deposit the semiconductor nanoparticles on the base material. It is preferable to repeat this application of the ink twice or more times. Regarding the conditions of the application, it is preferable to perform the application at a rotation speed of 500 to 5000 rpm for a rotation time of 10 to 300 seconds.

In addition, in the present invention, a firing treatment is performed after the application of the semiconductor nanoparticle ink, whereby a semiconductor nanoparticles light-receiving layer having suitable photoresponsivity is produced. In this firing step, the crystallinity of the semiconductor nanoparticles (AgBiS₂ nanoparticles and Ag₂S nanoparticles) on the base material is enhanced by heating, and the crystallite diameter is made to be within the above-described preferable range. The firing temperature at this time is set to 200° C. or higher and 350° C. or lower. At lower than 200° C., the crystallite diameter does not fall into the predetermined range, and the effect of improving responsiveness is weak. In addition, since the protective agent adsorbed to the particle surfaces does not sufficiently volatilize, charges around the particles become biased, and a state where the quantum confinement effect has been impaired is formed. When the firing temperature is set to 200° C. or higher, the crystallinity improves, and an effect of improving the responsiveness is expected. At this time, while there is a possibility that the protective agent may slightly remain on the particle surfaces, the protective agent is removed in a quantity large enough to prevent the quantum confinement effect from being impaired. However, when the upper limit of the firing temperature exceeds 350° C., the crystallite diameter becomes large owing to excessive crystallization. In addition, there is a concern of the precipitation of Ag caused by the decomposition of the compound or the breakage of the semiconductor film caused by the generation of a compound diverging from a desired chemical composition or the like. This firing treatment is preferably performed in an inert gas (nitrogen, argon or the like), and the treatment time is preferably set to 0.5 hours or longer.

The firing temperature of the semiconductor nanoparticles after the application of the ink is more preferably from 200° C. to 250° C. Even with the firing treatment at 250° C. or higher, an effect of improving a photoresponse is expected from the viewpoint of crystallinity. However, for AgBiS₂ in particular, the firing treatment at 250° C. or higher is a treatment that is performed beyond the three-phase eutectic point, and once dissolves the semiconductor particles, and thus the stability of the film may be affected.

When the above-described firing step has been completed, a light-receiving layer including a semiconductor thin film having a predetermined crystallite diameter is formed. In addition, when wires enabling the electrical connection with the light-receiving layer are formed as appropriate, it is possible to produce a photoelectric conversion element.

### ADVANTAGEOUS EFFECTS OF INVENTION

As described above, the present invention relates to a photoelectric conversion element material including a light-receiving layer composed of Ag₂₋ₓBiₓSₓ₊₁ (x is an integer of 0 or 1), which is a metal chalcogenide. This light-receiving layer is composed of the semiconductor nanoparticles of the above-described metal chalcogenide and has photoresponsivity in the near infrared region. In particular, when the crystallite diameter of the light-receiving layer including a semiconductor is set within a predetermined range, the responsiveness to light in the near infrared region improves.

### BRIEF DESCRIPTION OF THE DRAWINGS

FIG. 1 is TEM photographs of AgBiS₂ nanoparticles produced in First Embodiment;

FIG. 2 is a view showing an XRD diffraction pattern of the AgBiS₂ nanoparticles produced in First Embodiment;

FIG. 3 is a view showing the result of a DSC analysis of the AgBiS₂ nanoparticles produced in First Embodiment;

FIG. 4 is a view showing the light absorption characteristic of a AgBiS₂ ink produced in First Embodiment;

FIG. 5 is a view showing XRD diffraction patterns of light-receiving layer surfaces of photoelectric conversion elements produced in First Embodiment;

FIG. 6 is photographs showing the observation results of the surface morphologies with AFM of the light-receiving layer surfaces of the photoelectric conversion elements produced in First Embodiment;

FIG. 7 is a view showing the PL measurement result of each photoelectric conversion element produced in First Embodiment;

FIG. 8 is graphs showing the result of an evaluation test of photoresponsivity of each photoelectric conversion element produced in First Embodiment;

FIG. 9 is a graph showing the comparison of the PL measurement results of the photoelectric conversion elements produced at firing temperatures of 200° C. and 500° C.;

FIG. 10 is graphs showing the comparison of the photoresponsivity of the photoelectric conversion elements produced at firing temperatures of 200° C. and 500° C.;

FIG. 11 is graphs showing the comparison among the photoelectric conversion elements (200° C. and 300° C.) produced in First Embodiment and a light-receiving layer including PbS;

FIG. 12 is graphs showing the result (high bias) of an evaluation test of photoresponsivity of each photoelectric conversion element produced in First Embodiment;

FIG. 13 is a TEM photograph of Ag₂S nanoparticles produced in Second Embodiment;

FIG. 14 is a view showing an XRD diffraction pattern of the Ag₂S nanoparticles produced in Second Embodiment;

FIG. 15 is a view showing the light absorption characteristic of a Ag₂S ink produced in Second Embodiment;

FIG. 16 is a view showing XRD diffraction patterns of light-receiving layer surfaces of photoelectric conversion elements produced in Second Embodiment;

FIG. 17 is photographs showing the observation results of the surface morphologies with AFM of the light-receiving layer surfaces of the photoelectric conversion elements produced in Second Embodiment;

FIG. 18 is a view showing the PL measurement result of each photoelectric conversion element produced in Second Embodiment;

FIG. 19 is graphs showing the result of an evaluation test of photoresponsivity of each photoelectric conversion element produced in Second Embodiment;

FIG. 20 is a graph showing the comparison of the PL measurement results of the photoelectric conversion elements produced at firing temperatures of 200° C. and 500° C.;

FIG. 21 is graphs showing the comparison of the photoresponsivity of the photoelectric conversion elements produced at firing temperatures of 200° C. and 500° C.; and

FIG. 22 is graphs showing the comparison among the photoelectric conversion elements (200° C. and 300° C.) produced in Second Embodiment and a light-receiving layer including PbS.

### DETAILED DESCRIPTION OF THE PREFERRED EMBODIMENTS

First Embodiment: Hereinafter, an embodiment of the present invention will be described. In the present embodiment, a photoelectric conversion element material provided with a light-receiving layer including AgBiS₂ as a semiconductor material was produced. Semiconductor nanoparticles of AgBiS₂ were synthesized to produce an ink, this ink was applied to and fired on a base material to form a light-receiving layer, thereby producing a photoelectric conversion element material. Subsequently, the morphology of a thin film, which served as the light-receiving layer, was observed and the photoresponse characteristic of a photoelectric conversion element was evaluated.

### [Production of AgBiS₂ Ink]

133.5 mg of silver acetate (Ag(OAc)), 386 mg of bismuth acetate (Bi(OAc)₃) and 5.5 mL of oleic acid were mixed together, the inside of a mixing container was substituted with a N₂ gas, and then the liquid mixture was stirred at 100° C. for one hour. A solution containing 33 mg of sulfur dissolved in 5 mL of oleylamine was added to this liquid mixture and reacted. During the reaction, the liquid mixture was left to stand and cooled. Subsequently, AgBiS₂ nanoparticles were separated and extracted with acetone, and the extraction liquid was centrifuged to collect the AgBiS₂ nanoparticles. Furthermore, the collected nanoparticles were mixed with toluene, again, extracted and centrifuged with acetone, thereby collecting the AgBiS₂ nanoparticles. These were added to toluene, which was a dispersion medium, to produce an ink (nanoparticle concentration: 0.04 M). This ink was black.

[Measurement of Particle Diameters and Crystallite diameter of AgBiS₂ Nanoparticles]

The particle diameters and crystallite diameter of the AgBiS₂ nanoparticles in the ink produced above were studied. In this study, the AgBiS₂ nanoparticles were observed with a transmission electron microscope (TEM) to measure the particle diameters (average particle diameter). In addition, the AgBiS₂ nanoparticles were supported by a SiO₂ powder from the ink and measured in a dry state. An XRD analyzer was Ultima IV produced by Rigaku Corporation, CuKα rays were used as characteristic X rays, and 0.1°/m in. was set as an analysis condition.

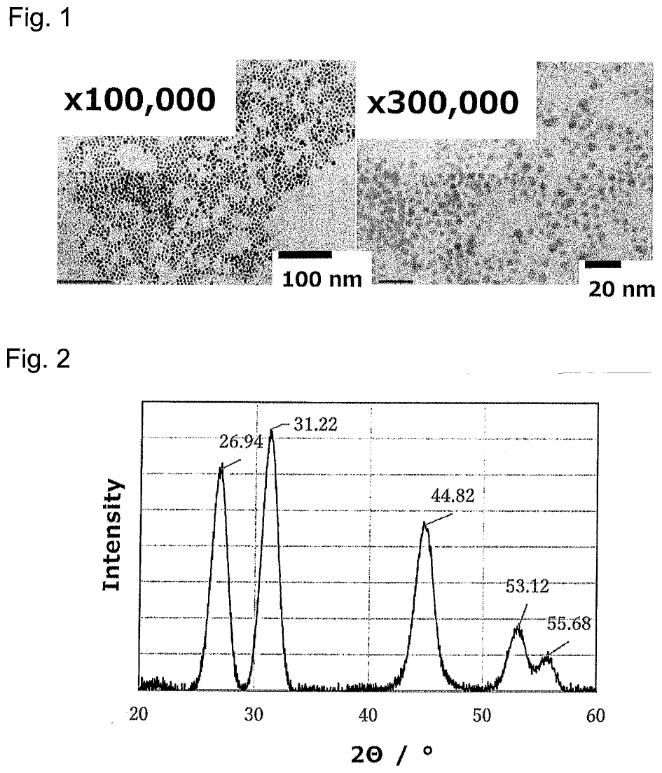

FIG. 1 is TEM images of the AgBiS₂ nanoparticles produced in the present embodiment. It was confirmed that nanoparticles having uniform particle diameters could be produced, and, as a result of an image analysis (binarized image analysis using ImageJ software), the average particle diameter was 8.75 nm. In addition, FIG. 2 shows the XRD diffraction pattern of the AgBiS₂ nanoparticles. The crystallite diameter of these AgBiS₂ nanoparticles was calculated to be 7.2 nm based on the diffraction peak at 2θ=near 31° from the full-width at half maximum of the peak.

### [Thermal Behaviors of AgBiS₂ Nanoparticles]

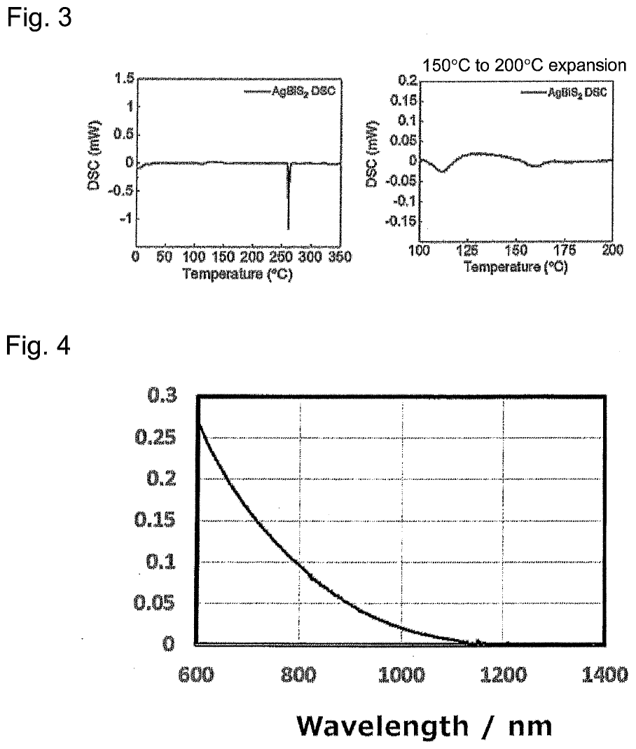

Next, the differential scanning calorimetry (DSC) of the AgBiS₂ nanoparticles was performed. The result is shown in FIG. 3. Heat peaks derived from the volatilization of the residual solvent at near 110° C. and the detachment of the protective agent at neat 160° C. were observed. That is, it is suggested that the excessive protective agent sufficiently volatilized at lower than 200° C. In addition, a large endothermic peak was detected at near 250° C. to 260° C. This can be considered to be a peak derived from the three-phase eutectic point of AgBiS₂.

### [Light Absorption Characteristic of AgBiS₂ Nanoparticles]

In order to confirm the optical semiconductor characteristic of the AgBiS₂ nanoparticles produced in the present embodiment, the light absorption characteristic was evaluated. The light absorption characteristic of a solution obtained by diluting the above ink 100 times was analyzed with a UV-Vis-NIR Spectrophotometer (UV-3600i Plus produced by Shimadzu Corporation).

The absorption spectrum of the AgBiS₂ ink is shown in FIG. 4. In this AgBiS₂ ink, it was confirmed that the absorption end extends up to a region exceeding a wavelength of 1000 nm and light absorption in the near infrared region is possible.

### [Formation of Light-Receiving Layer]

After a variety of characteristics of the above AgBiS₂ nanoparticles and ink were confirmed, this ink was applied to a base material to form a light-receiving layer, thereby producing a photoelectric conversion element material. As the base material, a silicon wafer (dimensions: 25×25, thickness: 0.6 mm) was prepared, and the above ink was applied to this base material. The application of the ink was performed by the spin coating method, the ink was dropped and applied onto the base material at a rotation speed of 2000 rpm (30 seconds) to form a semiconductor layer. In the present embodiment, this application step was repeated three times, and the amount of the ink applied per step was set to 0.1 mL (the mass of the nanoparticles: 2.8 mg).

After the application of the AgBiS₂ ink, the semiconductor layer was made into a light-receiving layer by a firing treatment. The firing treatment was performed in a nitrogen atmosphere at seven patterns of the treatment temperature set to 150° C., 200° C., 250° C., 300° C., 350° C., 400° C. and 500° C. The treatment time was set to 0.5 hours.

### [Measurement of Crystallite Diameter and Surface Roughness of Light-Receiving Layer (XRD and AFM)]

For seven photoelectric conversion elements produced by the above-described seven patterns of firing, XRD analyses were performed on semiconductor thin films that configured the light-receiving layers, and the crystallite diameters were calculated. In the XRD analyses, the thin films on the silicon wafers were measured as they were. The XRD analyses were performed with the same device under the same conditions as those in the analysis of the nanoparticles. In addition, the images of the surface morphologies of the light-receiving layers were captured and the surface roughness was measured with an atomic force microscope (AFM: NANOCUTE produced by Hitachi High-Tech Science Corporation).

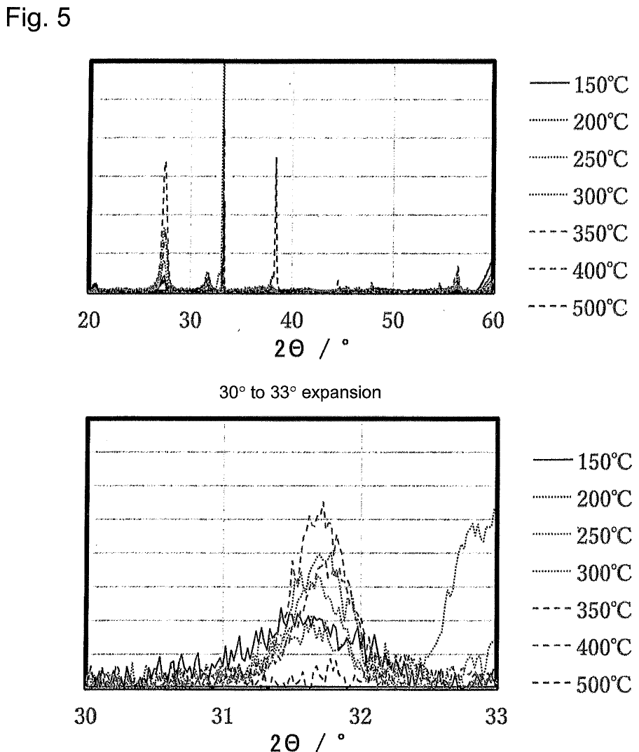

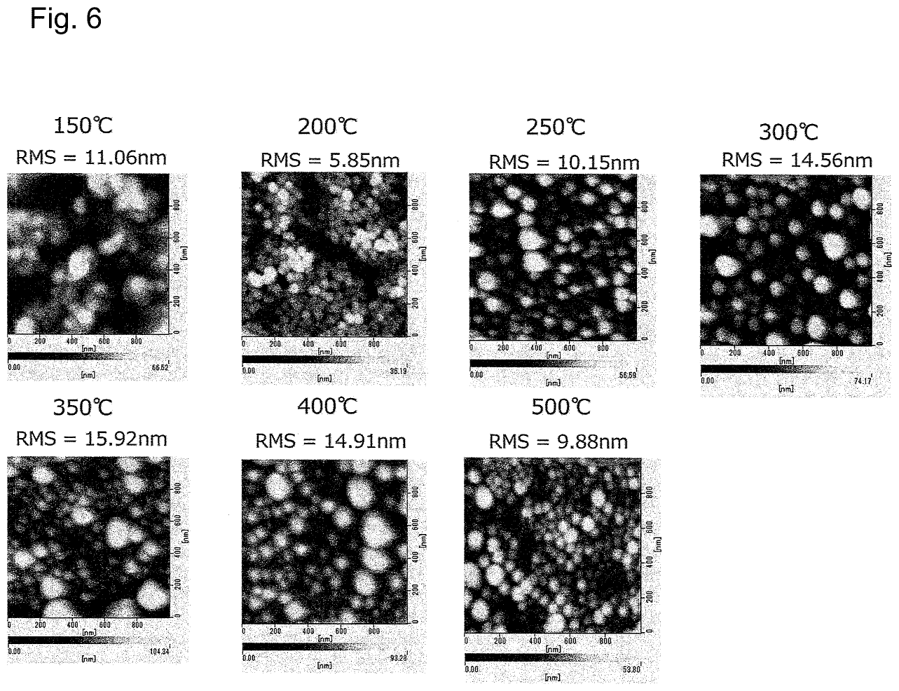

FIG. 5 shows the XRD diffraction patterns of the light-receiving layer surfaces of the above-described seven photoelectric conversion elements. When diffraction peaks of this diffraction pattern at near 27° are observed, it is confirmed that, as the firing temperature increases, the peak intensity becomes higher, and a sharp peak having a narrower full-width at half maximum is developed. From this fact, it can be seen that, when the firing temperature is set to be high, the crystallinity improves. Therefore, as a result of calculating crystallite diameters based on diffraction peaks at near 31°, the following values were obtained. In addition, FIG. 6 is the observation results of the light-receiving layer surface morphologies with AFM. The measurement results of the surface roughness with AFM are shown in Table 1.

TABLE 1

| No. | Firing temperature | Crystallite diameter | Surface roughness |
|---|---|---|---|
| 1 | 150° C. | 8.26 nm | 2.44 nm |
| 2 | 200° C. | 13.77 nm | 1.60 nm |
| 3 | 250° C. | 19.21 nm | 9.99 nm |
| 4 | 300° C. | 22.32 nm | 9.05 nm |
| 5 | 350° C. | 21.29 nm | 2.42 nm |
| 6 | 400° C. | 47.74 nm | 12.48 nm |
| 7 | 500° C. | —*¹ | 9.88 nm |

*¹No peaks are clearly observed at near 31° and thus calculation is not possible.

From Table 1, it can be seen that, as the temperature of the firing treatment increases, the crystallite diameter of the thin film becomes larger.

Particularly, at 200° C. or higher, improvement in the crystallinity is shown. However, when the firing temperature reaches 500° C., from the fact that the peak at near 31° vanishes in smoke and a Ag-derived peak near pure 38.3° becomes clear, it can be seen that the decomposition of AgBiS₂ occurs at this firing temperature.

In addition, when the relationship between the firing temperature and the surface roughness of the thin film is observed, the surface roughness does not change at firing temperatures of up to 200° C., the surface roughness increases at 250° C. to 300° C., and the surface roughness once returns to the original at 300° C. to 350° C.

This is considered to be related to the fact that, during the firing at a temperature exceeding the three-phase eutectic point of AgBiS₂, which was confirmed in the DSC analysis of the AgBiS₂ nanoparticles (near 250° C. to 260° C.), the AgBiS₂ nanoparticles once dissolve. Therefore, it is deemed that there is no complete proportional relationship between the firing temperature and the surface roughness. However, when the firing temperature exceeds 400° C., the surface roughness increases at once, and the AgBiS₂ particles coarsen. This point matches the fact that, in the XRD diffraction profiles, the diffraction peaks at near 27° rapidly increase at 400° C. In addition, during the firing at 500° C., even when the surface roughness decreases owing to the decomposition of AgBiS₂, the AgBiS₂ particles become islands.

### [Measurement of Photoluminescence]

After the configurations of the light-receiving layers were confirmed as described above, as a preliminary evaluation of the optical semiconductor characteristics of the photoelectric conversion element materials produced in the present embodiment, the photoluminescence (PL) was measured. Here, the measurement was performed using the photoelectric conversion element materials produced by the firing treatments performed at 150° C., 200° C. and 300° C. The PL measurement was conducted using LabRam Aramis produced by Horiba, Ltd. as the measurement device within a range of 500 to 1000 nm as a measurement condition.

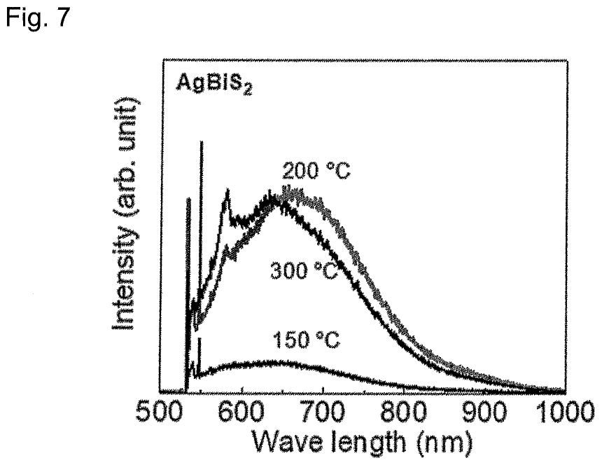

The PL measurement result of each photoelectric conversion element material is shown in FIG. 7. When the PL measurement results are observed in consideration of the previous XRD measurement results, it can be seen that the firing treatments at 200° C. or higher improve the crystallinity of the thin films and increase PL.

### [Evaluation of Photoresponse Characteristic]

For the photoelectric conversion element materials produced in the present embodiment, the photoresponse characteristics were evaluated. In this evaluation test, the photoelectric conversion element materials produced by the firing treatments at 150° C., 200° C. and 300° C. were used, and an electrode was formed on the light-receiving layer surface of each material by patterning a Ti film (film thickness: 5 nm) and a Au film (film thickness: 40 nm) in this order in a comb shape by a thermal deposition method, thereby producing a sample. In addition, a bias voltage of 0.5 V was loaded with a multimeter connected to the electrode, and a photocurrent owing to pulse irradiation of a near infrared light source was measured. The wavelengths of near infrared rays were set to 740 nm, 850 nm and 940 nm, and the pulse irradiation with the near infrared rays was performed in a manner of 20-second ON/40-second OFF.

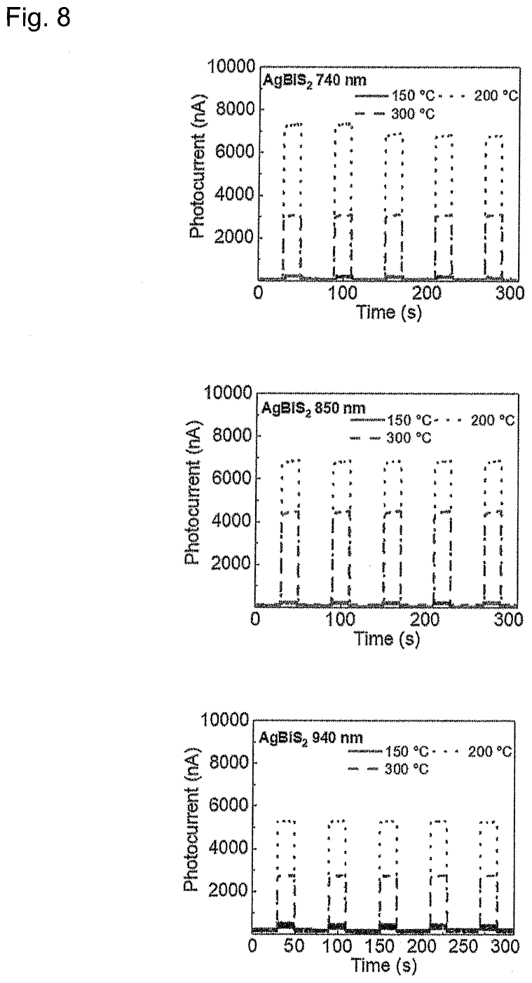

These photocurrent measurement results are shown in FIG. 8. In the AgBiS₂ thin films for which the firing treatment at 200° C. or higher was performed and the crystallite diameter of the thin film was adjusted, it can be seen that improvement in photoresponsivity was shown. In the case of this test, a particularly favorable increase in photocurrent was shown in the sample for which, particularly, the firing treatment at 200° C. was performed (crystallite diameter: 13.77 nm).

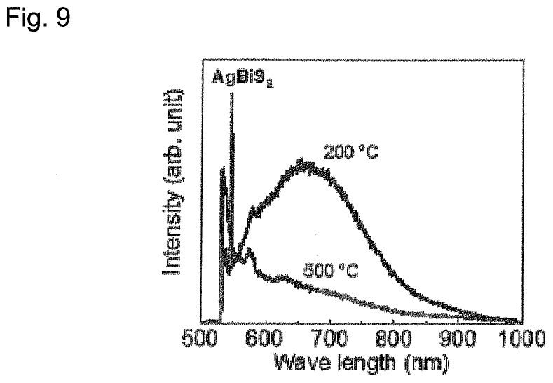

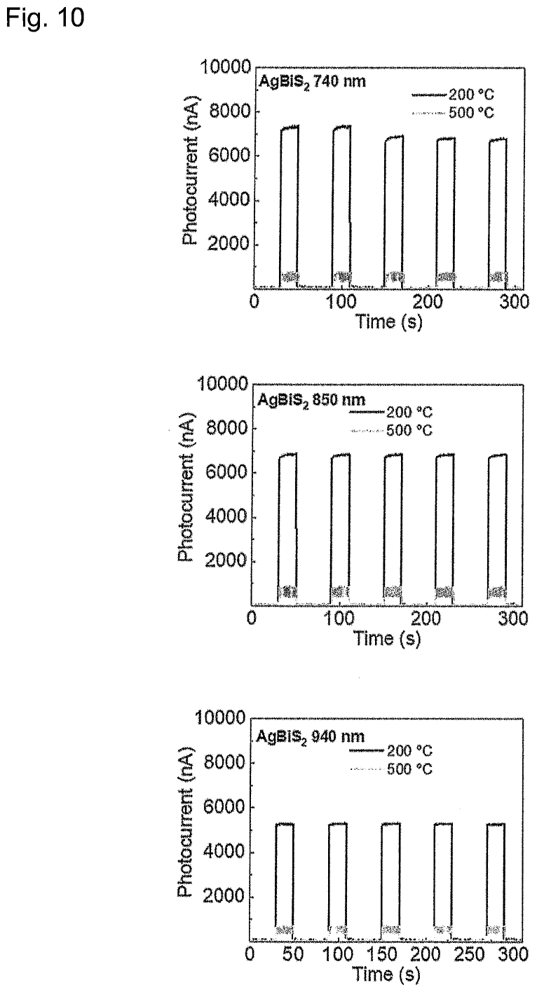

Furthermore, in order to confirm the influence of the firing temperature of higher than 350° C., PL measurement and photoresponsivity evaluation were performed on the light-receiving layer produced by the firing treatment at 500° C. These results are shown in FIG. 9 and FIG. 10 while being compared with those of the light-receiving layer produced by firing at 200° C. From the PL measurement results of FIG. 9, it can be seen that the light-emitting peak almost disappeared in the AgBiS₂ thin film fired at 500° C. In addition, from the photocurrent measurement results of FIG. 10, it was confirmed that a photoresponse is rarely exhibited in the AgBiS₂ thin film fired at 500° C. As a result of analyzing this AgBiS₂ thin film fired at 500° C. by SEM-EDS, the crystal structure of AgBiS₂ collapsed and the presence of particles was confirmed.

Here, in the present embodiment, comparison with photoelectric conversion elements including a PbS thin film, which has been conventionally known as a metal chalcogenide thin film having responsiveness in the near infrared region, as a light-receiving layer was performed. An ink in which commercially available PbS particles (Sigma-Aldrich) had been dispersed was produced, and this was applied to the same base material as in the present embodiment. In addition, the evaluation test of photoresponsivity was performed in the same manner as described above.

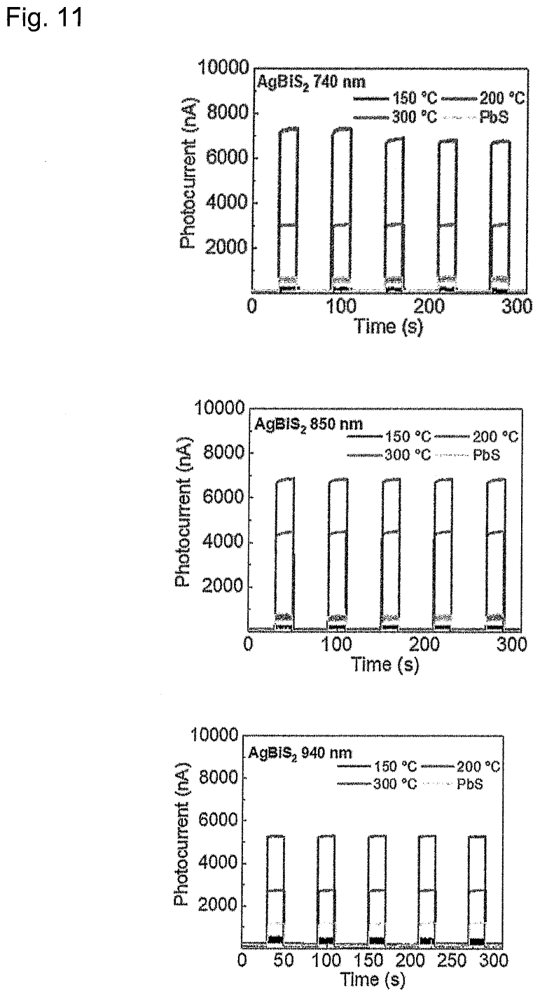

The results are shown in FIG. 11 together with the photoelectric conversion elements of the present embodiment (firing temperatures: 150° C., 200° C. and 300° C.). In the photoelectric conversion elements including PbS in the light-receiving layer, it was recognized that a photocurrent was once generated, but the photoelectric conversion elements (200° C. and 300° C.) including the AgBiS₂ thin film as the light-receiving layer of the present embodiment emit a higher photocurrent than that from this related art. Therefore, it has been clarified that the photoelectric conversion element of the present invention has superiority to the related art.

Next, as the photoresponse characteristic evaluation of the photoelectric conversion element, evaluation was performed when the bias during photocurrent measurement was set to a high bias. In this evaluation, a commercially available Ag nanopaste was applied to the light-receiving layer surface by screen printing, and a wire having a thickness of approximately 1 μm was formed in a comb shape, thereby producing a sample. In addition, a bias voltage of 2.0 V was loaded with a multimeter connected to an electrode, and a photocurrent owing to pulse irradiation of the near infrared light source was measured. The wavelengths of near infrared rays were set to 850 nm and 940 nm, and the pulse irradiation with the near infrared rays was performed in a manner of 10-second ON/10-second OFF.

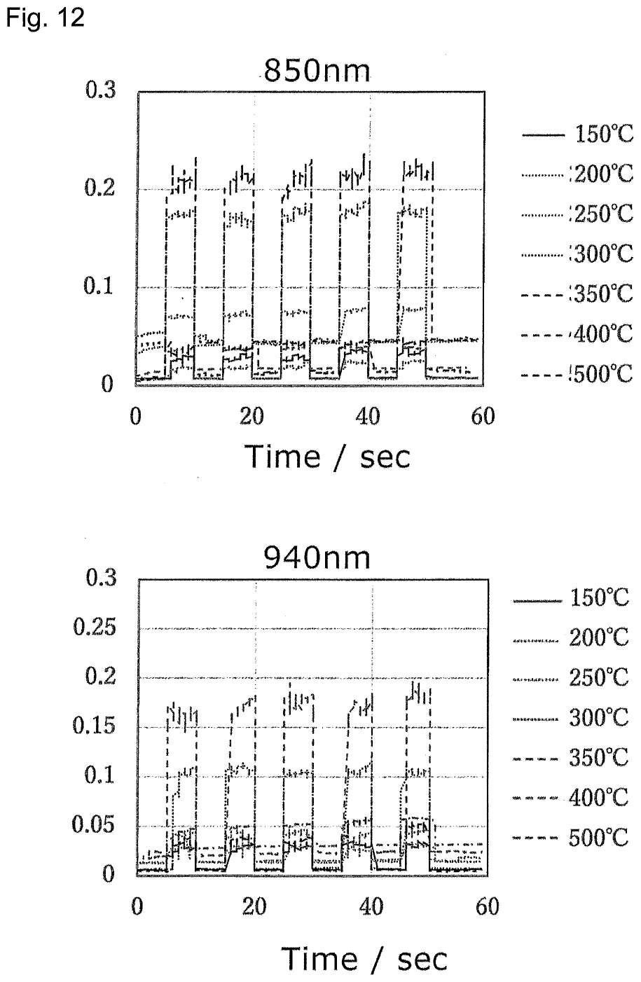

The results of these photoresponsivity evaluation tests are shown in FIG. 12. From FIG. 12, regarding the photoresponsivity under a high bias, significant increases in the photocurrent were shown particularly in the thin films fired at 300° C. and 350° C. (crystallite diameters: 22.32 nm and 21.29 nm).

Second Embodiment: In the present embodiment, a photoelectric conversion element material provided with a light-receiving layer including Ag₂S as a semiconductor thin film was produced. After semiconductor nanoparticles of Ag₂S were synthesized and an ink was produced in the same manner as in First Embodiment, the ink was applied to and fired on a base material to manufacture a photoelectric conversion element material.

### [Production of Ag₂S Ink]

134 mg of silver acetate, 30.5 mg of thiourea, 11.8 mL of oleylamine and 0.2 mL of dodecanethiol were mixed together, and a liquid mixture was stirred and reacted at 200° C. for 10 minutes. After the reaction, the liquid mixture was left to stand and cooled. Subsequently, Ag₂S nanoparticles were separated and extracted with methanol, and the extraction liquid was centrifuged to collect the Ag₂S nanoparticles. Furthermore, the collected nanoparticles were mixed with toluene, again, extracted and centrifuged with methanol, thereby collecting the Ag₂S nanoparticles. These were added to toluene, which was a dispersion medium, to produce an ink (nanoparticle concentration: 0.04 M). This ink was light brownish transparent.

### [Measurement of Particle Diameters and Crystallite Diameters of Ag₂S Nanoparticles]

The particle diameters and crystallite diameters of the Ag₂S nanoparticles in the ink produced above were studied. Particle diameter (average particle diameter) measurement and XRD analysis were performed with TEM under the same conditions as in First Embodiment.

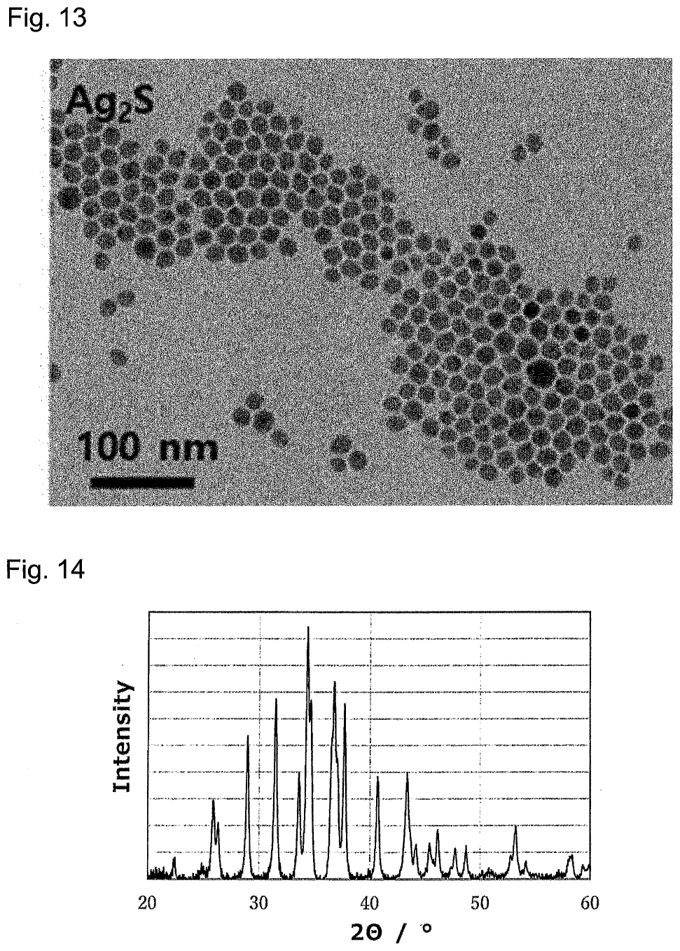

FIG. 13 is a TEM image of the Ag₂S nanoparticles produced in the present embodiment. In this case as well, it was confirmed that nanoparticles having uniform particle diameters could be produced, and the average particle diameter was 14.86 nm. In addition, FIG. 14 shows the XRD diffraction pattern of the AgBiS₂ nanoparticles. The crystallite diameter of these Ag₂S nanoparticles was calculated to be 17.2 nm based on the diffraction peak at 2θ=near 38° from the full-width at half maximum of the peak.

### [Light Absorption Characteristic of Ag₂S Nanoparticles]

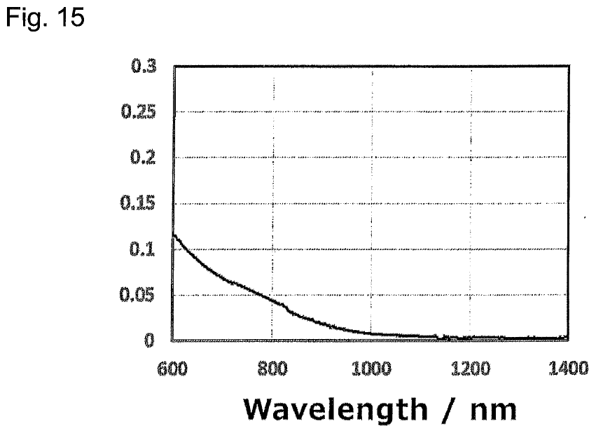

The measurement result of the light absorption characteristic of the Ag₂ S ink by the same method as in First Embodiment is shown in FIG. 15. In the Ag₂S ink as well, it was confirmed that the absorption end extends up to a region exceeding a wavelength of 1000 nm and light absorption in the near infrared region is possible.

### [Formation of Light-Receiving Layer]

After the above-described studies were performed, the Ag₂S ink was applied to a base material to form a light-receiving layer, thereby producing a photoelectric conversion element material. The Ag₂S ink was applied to a silicon wafer, which was the base material, in the same manner as in First Embodiment. A method for applying the ink was the same as that in First Embodiment. After the application of the Ag₂S ink, a firing treatment was performed in the same manner as in First Embodiment, thereby forming a light-receiving layer. The firing treatment was performed in a nitrogen atmosphere at treatment temperatures set to 150° C., 200° C., 250° C., 300° C., 350° C., 400° C. and 500° C.

### [Measurement of Crystallite Diameter and Surface Roughness of Light-Receiving Layer (XRD and AFM)]

For seven photoelectric conversion element materials of the present embodiment, XRD analyses were performed on semiconductor thin films that configured the light-receiving layers, and the crystallite diameters were calculated. In addition, the images of the surface morphologies of the light-receiving layers were captured and the surface roughness was measured with an atomic force microscope.

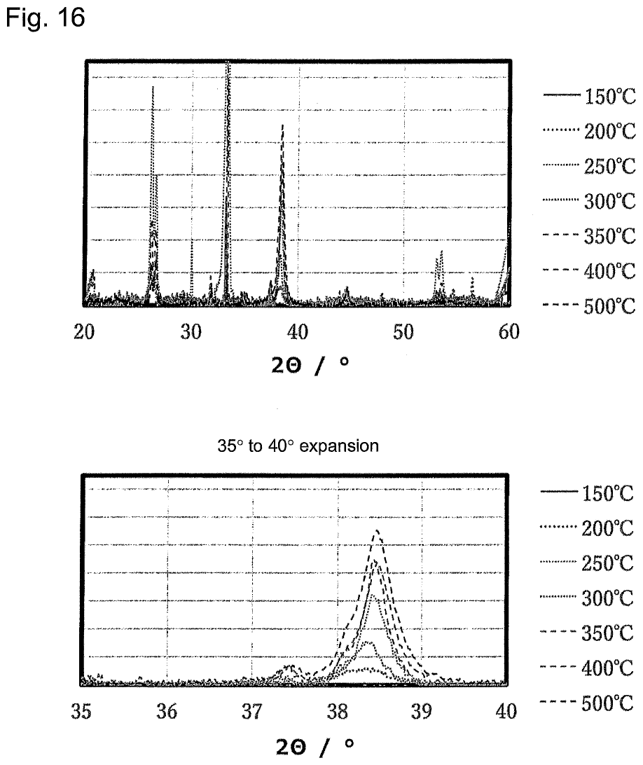

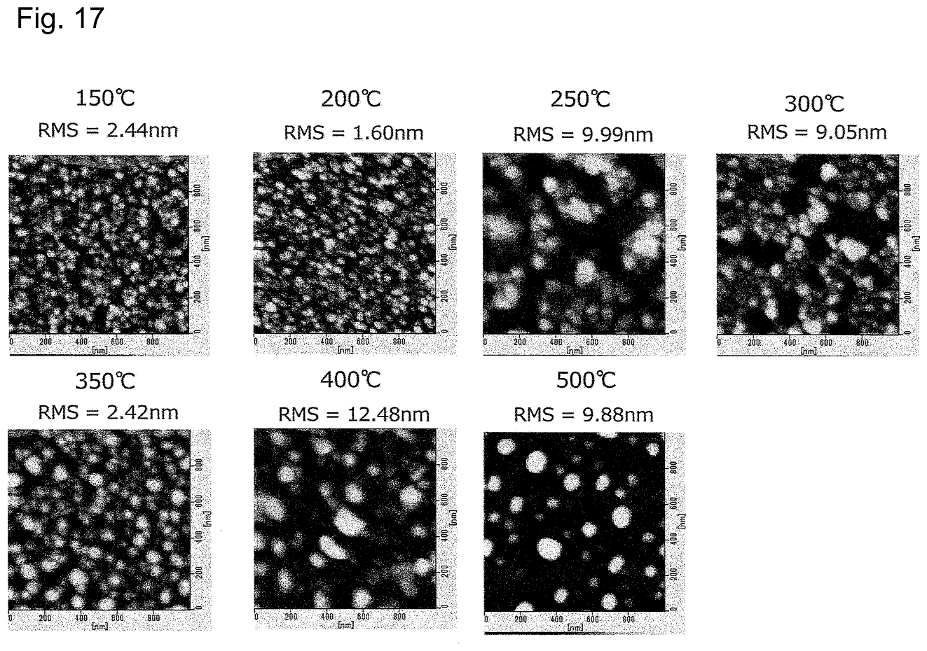

FIG. 16 shows the XRD diffraction pattern of the light-receiving layer surface of each photoelectric conversion element material. In addition, FIG. 17 is the observation results of the light-receiving layer surface morphologies with AFM. The values of the crystallite diameter and the surface roughness calculated based on the diffraction peaks at near 38° in the XRD diffraction pattern are shown in Table 2.

TABLE 2

| No. | Firing temperature | Crystallite diameter | Surface roughness | |
|---|---|---|---|---|
| 1 | 150° C. | —*¹ | 11.06 | nm |
| 2 | 200° C. | 13.26 nm | 5.85 | nm |
| 3 | 250° C. | 13.26 nm | 10.15 | nm |
| 4 | 300° C. | 17.97 nm | 14.56 | nm |
| 5 | 350° C. | 24.82 nm | 15.92 | nm |
| 6 | 400° C. | 11.59 nm | 14.91 | nm |
| 7 | 500° C. | 17.70 nm | 9.88 | nm |

*¹Peaks at near 38° are extremely small and thus calculation is not possible.

The behaviors of the particles by the firing treatment of the light-receiving layer including the Ag₂S thin film of the present embodiment are basically the same as those in the light-receiving layer including the AgBiS₂ thin film of First Embodiment. That is, as the temperature of the firing treatment increases, the crystallite diameter of the thin film becomes larger; however, when the firing temperature becomes a high temperature, the decomposition of Ag₂S occurs. In the present embodiment, the peak of Ag₂S at near 38° when fired at 150° C. was too small to calculate the crystallite diameter. In addition, in the relationship between the firing temperature and the surface roughness of the thin film as well, the surface roughness does not change at firing temperatures of relatively low temperatures, but it is observed that the surface roughness increases during the firing at 250° C. or higher and it is presumed that the crystal structure changes in this firing as well. During the firing at 500° C., Ag₂S decomposes, and Ag₂S particles become islands.

### [Measurement of Photoluminescence]

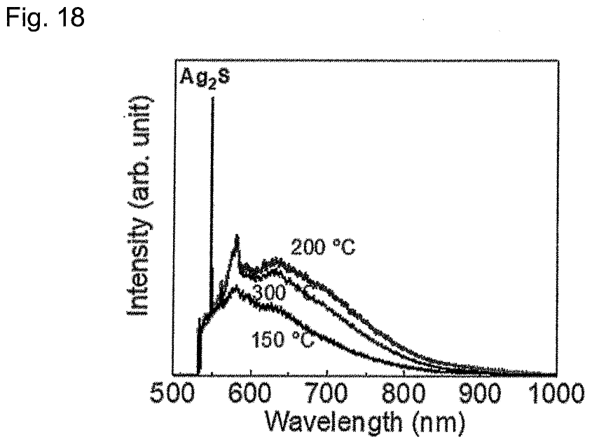

Furthermore, the PL measurement results of the photoelectric conversion element materials provided with the light-receiving layer including Ag₂S produced in the present embodiment are shown in FIG. 18. In the present embodiment as well, it can be seen that the firing treatments improve the crystallinity of the thin films and increase PL.

### [Evaluation of Photoresponse Characteristic]

In addition, for the photoelectric conversion element materials provided with the light-receiving layer including Ag₂S produced in the present embodiment, the photoresponse characteristics were evaluated. Here, photocurrents were measured from photoelectric conversion elements produced by the firing treatments at 150° C., 200° C. and 300° C. with the same samples under the same measurement conditions as in the photocurrent measurement under a low bias condition (0.5 V) in First Embodiment.

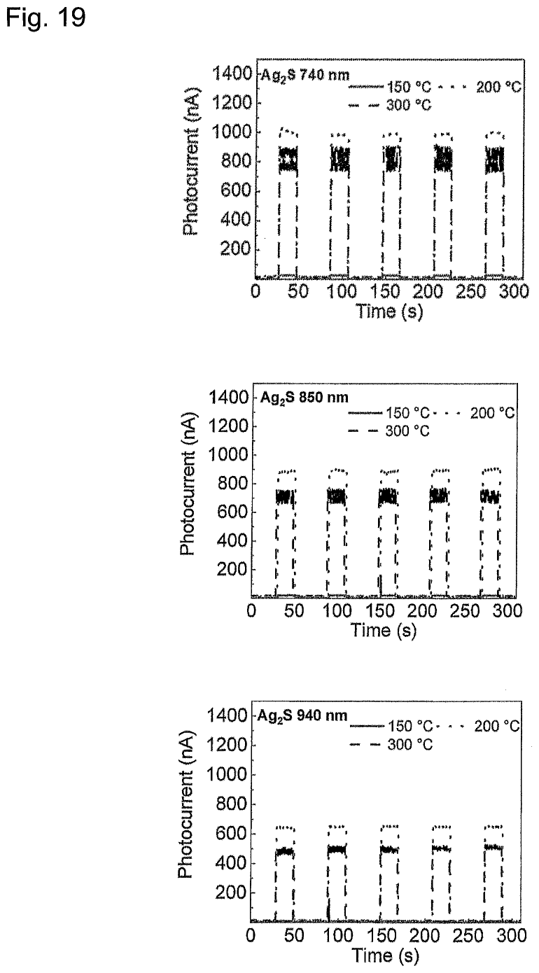

The photocurrent measurement results of the photoelectric conversion elements provided with the light-receiving layer including Ag₂S are shown in FIG. 19. In the present embodiment as well, a particularly favorable increase in photocurrent is shown in the sample for which, particularly, the firing treatment at 200° C. was performed (crystallite diameter: 13.26 nm). It was confirmed that the light-receiving layers fired at 200° C. or higher exhibited clear photoresponsivity with respect to the light-receiving layer fired at 150° C., which was also the same as in the light-receiving layers including AgBiS₂ of First Embodiment.

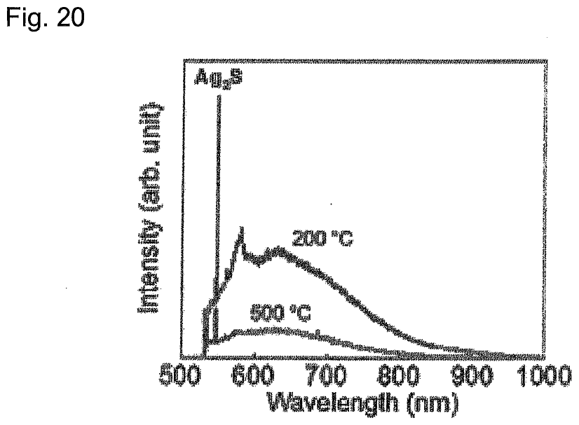

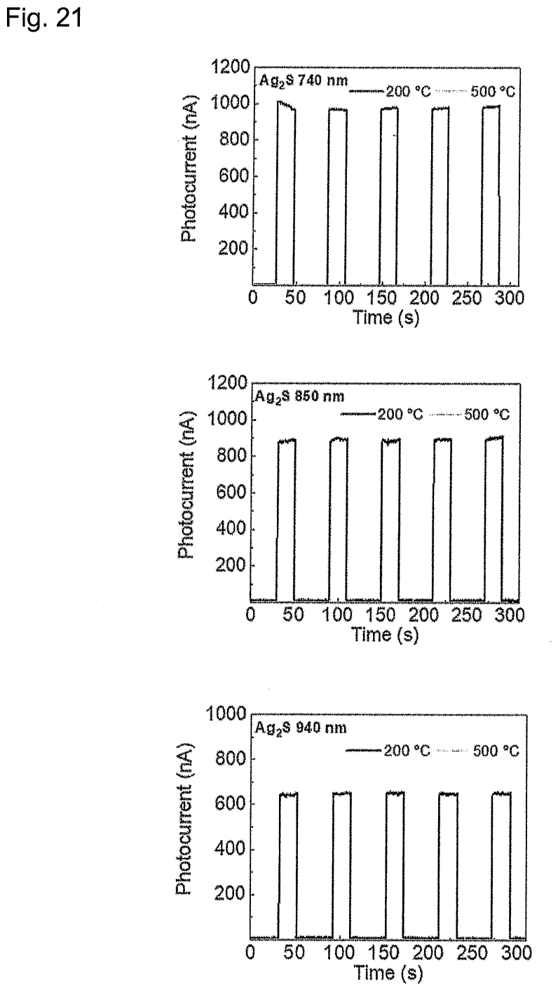

Furthermore, in the present embodiment as well, PL measurement and photoresponsivity evaluation were performed on the light-receiving layers including Ag₂S produced by the firing treatment at 500° C. These results are shown in FIG. 20 and FIG. 21. From the PL measurement results of FIG. 20, it can be seen that the light-emitting peak disappeared in the Ag₂S thin film fired at 500° C. In addition, from the photoresponsivity evaluation results of FIG. 21, it was confirmed that a photoresponse is rarely exhibited in the Ag₂S thin film fired at 500° C. In the present embodiment as well, as a result of analyzing this Ag₂S thin film fired at 500° C. by SEM-EDS, it was confirmed that the composition of Ag₂S collapsed.

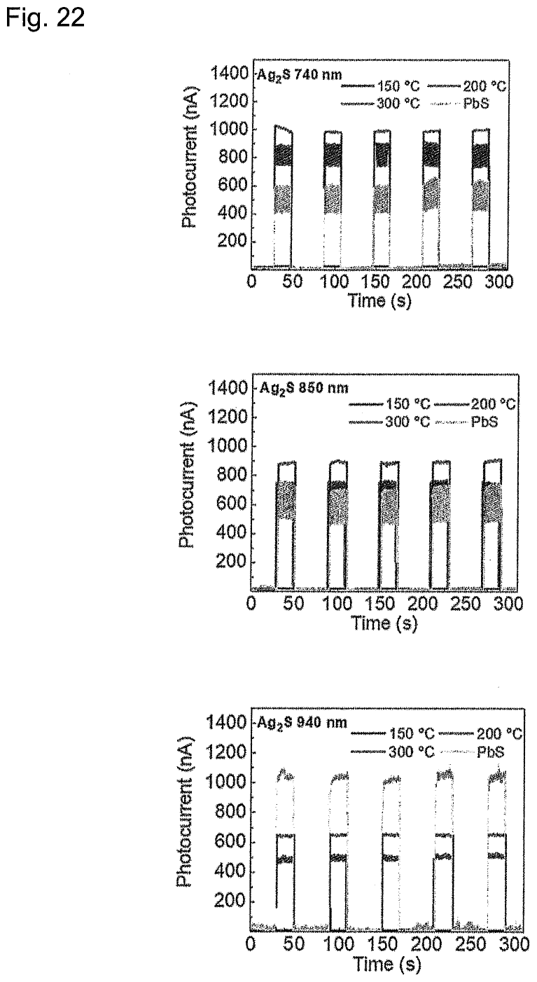

In addition, comparison between the light-receiving layers including Ag₂S of the present embodiment and the light-receiving layer including PbS, which is the related art, is shown in FIG. 22. When compared with AgBiS₂ of First Embodiment, Ag₂S is not superior to PbS as much as AgBiS₂. However, at 740 nm and 850 nm, the photocurrent value becomes higher in Ag₂ S than PbS. Regarding this fact, since AgBiS₂ of First Embodiment exhibits a far more favorable photoresponse than PbS in a region of 940 nm, the possibility of applying AgBiS₂ as a near infrared light-receiving element is further expected.

### INDUSTRIAL APPLICABILITY

As described above, the photoelectric conversion element material of the present invention is provided with a semiconductor film including Ag₂₋ₓBiₓSₓ₊₁ (x is an integer of 0 or 1), which is a metal chalcogenide, as a light-receiving layer. This light-receiving layer exhibits excellent responsiveness to light in the near infrared region by being imparted with appropriate crystallinity. The present invention is particularly useful as a photoelectric conversion thin film for a light-receiving element for a variety of optical semiconductor devices and is expected to contribute to the size reduction or performance improvement of LIDAR or image sensors as a light-receiving element therefor.

1. A photoelectric conversion element material comprising:
a base material; and
a light-receiving layer comprising a semiconductor film formed on the base material,
wherein the semiconductor film comprises Ag₂₋ₓBiₓSₓ₊₁ (x is an integer of 0 or 1), and
the semiconductor film has a crystallite diameter of 10 nm or more and 40 nm or less.

2. The photoelectric conversion element material according to claim 1, wherein the semiconductor film has a crystallite diameter of 10 nm or more and 25 nm or less.

3. The photoelectric conversion element material according to claim 1, wherein the semiconductor film has a surface roughness of 2 nm or more and 15 nm or less.

4. The photoelectric conversion element material according to claim 1, wherein the photoelectric conversion element material has responsiveness to light having wavelengths of 700 nm or more and 1200 nm or less.

5. An ink comprising semiconductor nanoparticles dispersed in a dispersion medium, wherein
the semiconductor nanoparticles comprise Ag₂₋ₓBiₓSₓ₊₁ (x is an integer of 0 or 1) and have a crystallite diameter of 5 nm or more and 20 nm or less,
the semiconductor nanoparticles are protected by a protective agent comprising at least any one of a long-chain alkylamine, a long-chain carboxylic acid and a thiol, and
the dispersion medium is an organic solvent with a low polarity.

6. A method for producing the photoelectric conversion element material defined in claim 1, the method comprising:
applying the ink comprising semiconductor nanoparticles dispersed in a dispersion medium, wherein
the semiconductor nanoparticles comprise Ag₂₋ₓBiₓSₓ₊₁ (x is an integer of 0 or 1) and have a crystallite diameter of 5 nm or more and 20 nm or less,
the semiconductor nanoparticles are protected by a protective agent comprising at least any one of a long-chain alkylamine, a long-chain carboxylic acid and a thiol, and
the dispersion medium is an organic solvent with a low polarity to a base material to form a semiconductor layer; and
firing the semiconductor layer to form a light-receiving layer,
wherein a firing temperature in the step of firing the semiconductor layer is 200° C. or higher and 350° C. or lower.

7. The photoelectric conversion element material according to claim 2, wherein the semiconductor film has a surface roughness of 2 nm or more and 15 nm or less.

8. The photoelectric conversion element material according to claim 2, wherein the photoelectric conversion element material has responsiveness to light having wavelengths of 700 nm or more and 1200 nm or less.

9. The photoelectric conversion element material according to claim 3, wherein the photoelectric conversion element material has responsiveness to light having wavelengths of 700 nm or more and 1200 nm or less.

10. A method for producing the photoelectric conversion element material defined in claim 2, the method comprising:
applying the ink comprising semiconductor nanoparticles dispersed in a dispersion medium, wherein
the semiconductor nanoparticles comprise Ag₂₋ₓBiₓSₓ₊₁ (x is an integer of 0 or 1) and have a crystallite diameter of 5 nm or more and 20 nm or less,
the semiconductor nanoparticles are protected by a protective agent comprising at least any one of a long-chain alkylamine, a long-chain carboxylic acid and a thiol, and
the dispersion medium is an organic solvent with a low polarity to a base material to form a semiconductor layer; and
firing the semiconductor layer to form a light-receiving layer,
wherein a firing temperature in the step of firing the semiconductor layer is 200° C. or higher and 350° C. or lower.

11. A method for producing the photoelectric conversion element material defined in claim 3, the method comprising:
applying the ink comprising semiconductor nanoparticles dispersed in a dispersion medium, wherein
the semiconductor nanoparticles comprise Ag₂₋ₓBiₓSₓ₊₁ (x is an integer of 0 or 1) and have a crystallite diameter of 5 nm or more and 20 nm or less,
the semiconductor nanoparticles are protected by a protective agent comprising at least any one of a long-chain alkylamine, a long-chain carboxylic acid and a thiol, and
the dispersion medium is an organic solvent with a low polarity to a base material to form a semiconductor layer; and
firing the semiconductor layer to form a light-receiving layer,
wherein a firing temperature in the step of firing the semiconductor layer is 200° C. or higher and 350° C. or lower.

12. A method for producing the photoelectric conversion element material defined in claim 4, the method comprising:
applying the ink comprising semiconductor nanoparticles dispersed in a dispersion medium, wherein
the semiconductor nanoparticles comprise Ag₂₋ₓBiₓSₓ₊₁ (x is an integer of 0 or 1) and have a crystallite diameter of 5 nm or more and 20 nm or less,
the semiconductor nanoparticles are protected by a protective agent comprising at least any one of a long-chain alkylamine, a long-chain carboxylic acid and a thiol, and
the dispersion medium is an organic solvent with a low polarity to a base material to form a semiconductor layer; and
firing the semiconductor layer to form a light-receiving layer,
wherein a firing temperature in the step of firing the semiconductor layer is 200° C. or higher and 350° C. or lower.
